(19) United States
(12) Patent Application Publication
(10) Pub. No.: US 2018/0334746 A1
(43) Pub. Date: Nov. 22, 2018

(54) Wafer Edge Contact Hardware and Methods to Eliminate Deposition at Wafer Backside Edge and Notch

(71) Applicant: Lam Research Corporation, Fremont, CA (US)

(72) Inventors: Patrick Breiling, Portland, OR (US); Ramesh Chandrasekharan, Portland, OR (US); Chloe Baldasseroni, Portland, OR (US); Sung Je Kim, Beaverton, OR (US); lshtak Karim, Portland, OR (US); Mike Roberts, Tigard, OR (US); Richard Phillips, Tualatin, OR (US); Purushottam Kumar, Hillsboro, OR (US); Adrien LaVoie, Newburg, OR (US)

(21) Appl. No.: 15/601,876

(22) Filed: May 22, 2017

(51) Int. Cl. C23C 16/455; C23C 16/50; C23C 16/458; H01L 21/687

(52) U.S. Cl. CPC C23C 16/45544; H01L 21/68771; C23C 16/458; C23C 16/50

(57) ABSTRACT

A pedestal assembly for a plasma processing system is provided. The assembly includes a pedestal with central top surface, e.g., mesa, and the central top surface extends from a center of the central top surface to an outer diameter of the central top surface. An annular surface surrounds the central top surface. The annular top surface is disposed at step down from the central top surface. A plurality of wafer supports project out of the central top surface at a support elevation distance above the central top surface. The plurality of wafer supports are evenly arranged around an inner radius of the center top surface. The inner radius is located between the center of the central top surface and less than a mid-radius that is approximately half way between the center of the pedestal and the outer diameter of the central top surface. A carrier ring configured for positioning over the annular surface of the pedestal is provided. The carrier ring has a carrier ring inner diameter, a carrier ring outer diameter, and a ledge surface that is annularly disposed around a top inner region of the carrier ring. The ledge surface is recessed below a top outer region of the carrier ring. A plurality of carrier ring supports are disposed outside of the annular surface of the pedestal. The carrier ring supports define a carrier ring elevation dimension of the carrier ring, above the central top surface of the pedestal, when the carrier ring rests upon the plurality of carrier ring supports. The carrier ring elevation dimension is configured to be higher than the central top surface of the pedestal than the support elevation distance.

### BACKGROUND

### 1. Field of the Invention

The present embodiments relate to semiconductor wafer processing equipment tools, and more particularly, carrier rings used in chambers. The chambers being for processing and transport of wafers.

### 2. Description of the Related Art

In atomic layer deposition (ALD), a film is deposited layer by layer by successive dosing and activation steps. ALD is used to generate conformal films on high aspect ratio structures. One of the drawbacks of ALD is that film deposition on the backside of the wafer is difficult to avoid because the film can be deposited through any gap accessing the wafer backside. Backside deposition is unwanted in spacer applications as it leads to alignment/focusing issues during lithography steps that are part of the integration flow.

Film on the backside is generated by transport of precursor species to the backside during the dose step, and reaction of the precursor by radical species transported during the activation step. Thus, there is a need to control or reduce wafer backside deposition.

It is in this context that embodiments of the inventions arise.

### SUMMARY

Embodiments of the disclosure provide systems, apparatuses, and methods to reduce backside deposition during ALD processing. In an ALD process chamber, a wafer is supported on a pedestal assembly which is fitted with a carrier ring positioned at a height relative to wafer supports to reduce backside deposition. In some embodiments, each pedestal assembly is calibrated to ensure wafer overlap is maintained over the carrier ring during processing, accounting for thermal expansion. Several embodiments will now be described.

In one embodiment, a pedestal assembly for a plasma processing system is provided. The assembly includes a pedestal with central top surface, e.g., mesa, and the central top surface extends from a center of the central top surface to an outer diameter of the central top surface. An annular surface surrounds the central top surface. The annular top surface is disposed at step down from the central top surface. A plurality of wafer supports project out of the central top surface at a support elevation distance above the central top surface. The plurality of wafer supports are evenly arranged around an inner radius of the center top surface. The inner radius is located between the center of the central top surface and less than a mid-radius that is approximately half way between the center of the pedestal and the outer diameter of the central top surface. A carrier ring configured for positioning over the annular surface of the pedestal is provided. The carrier ring has a carrier ring inner diameter, a carrier ring outer diameter, and a ledge surface that is annularly disposed around a top inner region of the carrier ring. The ledge surface is recessed below a top outer region of the carrier ring. A plurality of carrier ring supports are disposed outside of the annular surface of the pedestal. The carrier ring supports define a carrier ring elevation dimension of the carrier ring, above the central top surface of the pedestal, when the carrier ring rests upon the plurality of carrier ring supports. The carrier ring elevation dimension is configured to be higher than the central top surface of the pedestal than the support elevation distance.

In one implementation, the plurality of wafer supports provide kinematic mating to a wafer when placed over the plurality of wafer supports.

In one implementation, the ledge surface of the carrier ring has a step that transitions to the top outer region of the carrier ring, and the ledge surface is elevated above the plurality of wafer supports by a carrier ring-support dimension.

In one implementation, the inner radius is about 2.5 inches and the outer diameter of the central top surface is about 11.5 inches.

In one implementation, an overlap surface region is defined over the ledge surface, and the overlap surface region defines a contact surface for a wafer under surface when disposed over the central top surface of the pedestal.

In one implementation, a plurality of spacers are disposed under the carrier ring supports to enable calibrated positioning of the carrier ring elevation dimension.

In one implementation, the inner radius of the plurality of wafer supports is located between the center and a quarter-radius, and the quarter-radius located between the mid-radius and the center.

In one implementation, the support elevation distance is between about 2 mils and about 6 mils, and the carrier ring elevation dimension is between about 1 mil and about 3 mils.

In one implementation, the support elevation distance is about 4 mils and the carrier ring elevation dimension is about 1.5 mils, and the inner radius is about 2.5 inches about the center of the central top surface of the pedestal.

In one implementation, the outer diameter of the central top surface is about 11.52 inches.

In one implementation, the plasma processing system is configured as a ringless transfer system. A ringless transfer system is configured to maintain the carrier ring disposed over the annular surface of the pedestal and a wafer is configured to be moved on and off the plurality of wafer supports and the ledge surface of the carrier ring. The pedestal includes lift pins for rising and lowering the wafer when present and the process system further includes transfer arms for moving wafers on and off of each one of a plurality of pedestal assemblies of the plasma processing system.

### BRIEF DESCRIPTION OF THE DRAWINGS

FIG. 1 illustrates a substrate processing system, which is used to process a wafer, e.g., to form films thereon.

FIG. 2 illustrates another substrate processing system, which is used to process a wafer, e.g., to form films thereon.

FIG. 3A illustrates a top view of a multi-station processing tool, wherein four processing stations are provided, in accordance with one embodiment.

FIG. 3B shows a schematic view of an embodiment of a multi-station processing tool with an inbound load lock and an outbound load lock, in accordance with one embodiment.

FIG. 3C illustrates a pedestal that is configured to receive a wafer for a deposition process, such as an atomic layer deposition (ALD) process, in accordance with an embodiment of the invention.

FIG. 3D illustrates a perspective cutaway view of a portion of the pedestal, in accordance with an embodiment of the invention.

FIG. 4A illustrates a cross-sectional view similar to that of FIG. 3D, with additional detail regarding the wafer support and the contact made by wafer on the ledge surface, in accordance with one embodiment.

FIG. 4B illustrates how the wafer support 304a is disposed in the pedestal 300, and has a portion thereof extending out of the central top surface, in accordance with one embodiment.

FIG. 4C illustrates the detail region of FIG. 4A, with more particularity, in accordance with one embodiment.

FIG. 5A illustrates detail region of FIG. 4C, which shows an overlap between the under edge surface of the wafer and the ledge surface of the carrier ring, in accordance with one embodiment.

FIGS. 5B through 5D illustrate an example of the thermal changes that may occur that would impact the overlap shown in FIG. 5A, during thermal processing, in accordance with one embodiment.

FIGS. 6A and 6B illustrate examples of reduced or substantially eliminated backside deposition to a wafer.

FIG. 7 shows a control module for controlling the systems, in accordance with one embodiment.

### DESCRIPTION

Embodiments of the disclosure provide embodiments of a process chamber, used for processing semiconductor wafers. It should be appreciated that the present embodiments can be implemented in numerous ways, such as a process, an apparatus, a system, a device, or a method. Several embodiments are described below. In one embodiment, a pedestal assembly is disclosed. The embodiment is defined by several elements which work together to reduce deposition on a backside of the wafer/device.

A wafer is contacted near the edge in a limited area, e.g., at the wafer edge, with a carrier ring and pins at the center, referred to as MCA pins. The pins at the wafer center lift the wafer center higher than the outer edge creating a wafer bowing condition. This allows for the wafer edge to contact the carrier ring with tangent or line contact. Due to the precision required and the limits of ‘on-site’ setup, the pins and carrier ring do not currently block enough deposition on the back of the wafer. The amount of contact to the back of the wafer is also limited with prior designs, so it is less tolerant of off-center wafer placement.

It is believed that backside deposition occurs when a gap occurs between a wafer edge and a carrier ring, during processing. In atomic layer deposition (ALD) operations, process precursors are pulsed over a wafer under vacuum for a designated amount of time to allow the precursor to fully react with the substrate surface through a self-limiting process that leaves a monolayer at the surface. Subsequently, the chamber is purged with an inert carrier gas (typically N2 or Ar) to remove any unreacted precursor or reaction by-products. Then, a counter-reactant precursor pulse and purge is executed to form the desired film of material. Unfortunately, the precursor has a tendency to flow in areas that are not intended for deposition, such as the backside of the wafer. Thus, it is one goal of the present application to define structures to limit or avoid backside deposition by configuration the elements of the pedestal in accordance with the examples provided herein.

In one embodiment, the pedestal assembly includes an aluminum pedestal with sapphire MCA (Minimum Contact Area) pins. The pedestal is a heated device which is controlled to temperature. The wafer rests on these pins and the height of the pins allows for a minimum gap between the pedestal and wafer. This gap is optimized for both thermal uniformity of the pedestal and wafer as well as pressure equalization between the top and bottom of the wafer in order to reduce movement of the wafer on the pedestal.

In another embodiment, a ceramic carrier ring (sometimes referred to as a focus ring) rests around the pedestal perimeter and is adjusted to a specific height, relative to the pedestal. The carrier ring rests on adjustable components, including precision shims, which control the height of the ring in relation to the pedestal. The carrier ring has a ledge surface 330a recessed from the top of it, which the wafer rests upon. In one embodiment, this surface is adjusted in order to be higher than the MCA pins on the pedestal by a prescribed amount. The width and contact of this ledge also ensures a specific minimum overlap with the wafer as it rests on it. In one embodiment, the overlap contacts flat portions of the wafer consistently. In one embodiment, the ledge also is above the MCA's so the contact force between the wafer and ring is consistent around the wafer perimeter. The carrier rings' diameters are designed to allow this overlap and function with the pedestal for specified temperature ranges.

It is understood that temperature changes impact size of parts, including the pedestal and the carrier ring, so sizing of the pedestal, the carrier ring, and overlap are designed to maintain wafer to carrier ring ledge contact even at elevated temperatures, e.g., up to 400 degrees Celsius or greater. In accordance with the disclosed embodiments, the sized diameters also prevent loss of contact from differential thermal expansion. By maintaining contact, wafers will see less stress or failure, which could result from loss of contact with the carrier ring during thermal size expansions. These embodiments therefore improve performance, stability, and function of the pedestal designs used in ALD systems.

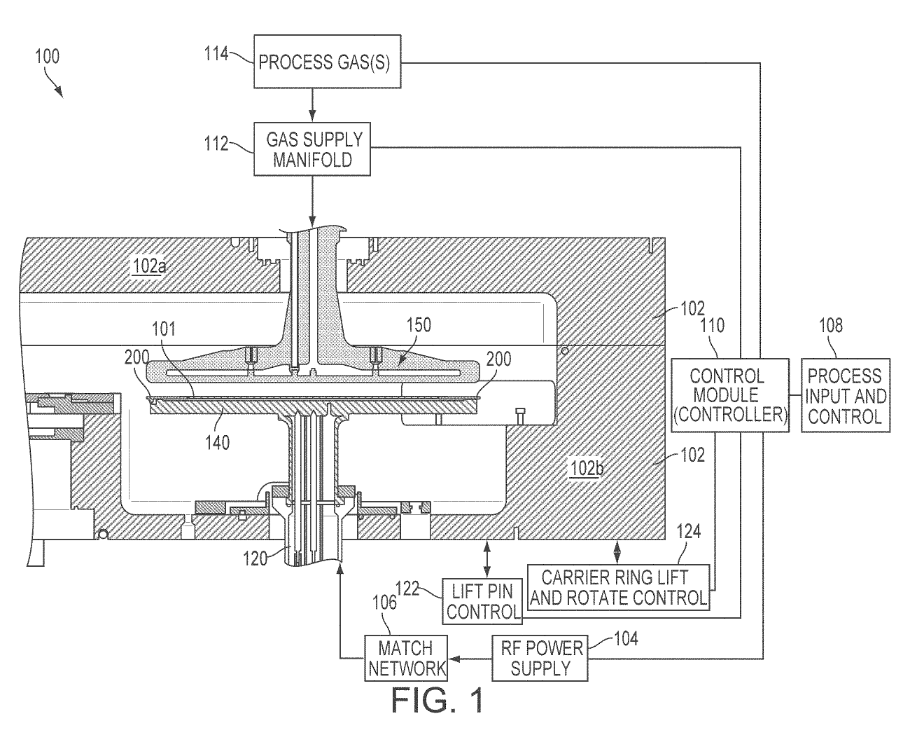

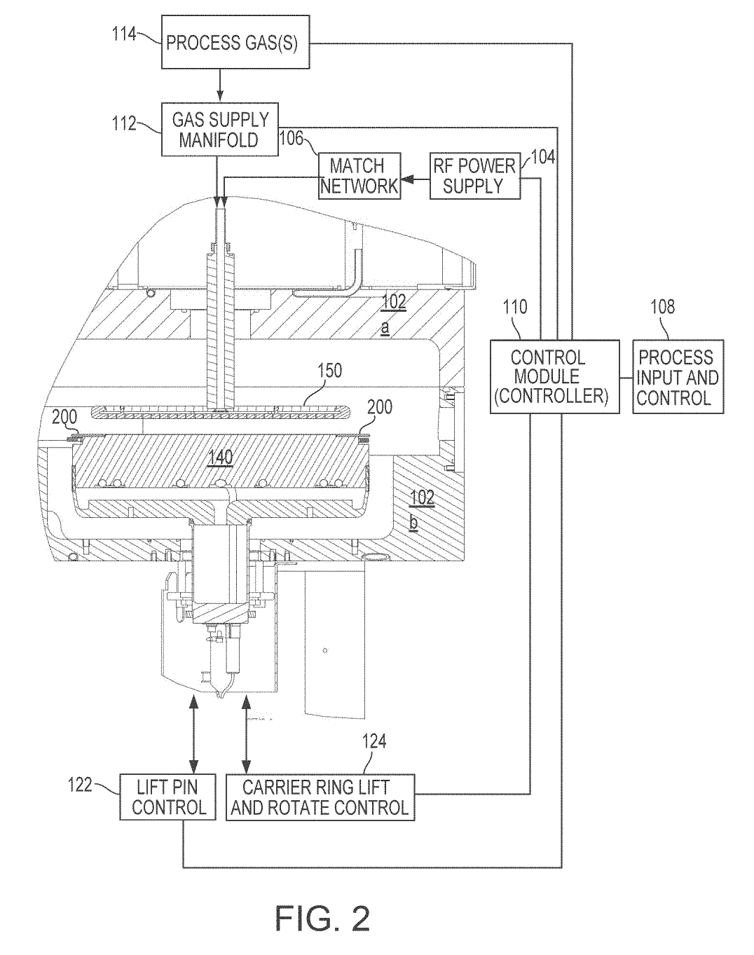

FIGS. 1 and 2 are provided below to illustrate two types of chambers, without limitation to other possible chamber configurations.

FIG. 1 illustrates a substrate processing system 100, which is used to process a wafer 101. The system includes a chamber 102 having a lower chamber portion 102b and an upper chamber portion 102a. A center column is configured to support a pedestal 140, which in one embodiment is a powered electrode. The pedestal 140 is electrically coupled to power supply 104 via a match network 106. The power supply is controlled by a control module 110, e.g., a controller. The control module 110 is configured to operate the substrate processing system 100 by executing process input and control 108. The process input and control 108 may include process recipes, such as power levels, timing parameters, process gasses, mechanical movement of the wafer 101, etc., such as to deposit or form films over the wafer 101. In some embodiments, the pedestal 140 includes a heater integrated into the body of the aluminum structure that defines the pedestal 140.

The center column is also shown to include lift pins 120, which are controlled by lift pin control 122. The lift pins 120 are used to raise the wafer 101 from the pedestal 140 to allow an end-effector to pick the wafer and to lower the wafer 101 after being placed by the end-effector. The substrate processing system 100 further includes a gas supply manifold 112 that is connected to process gases 114, e.g., gas chemistry supplies from a facility. Depending on the processing being performed, the control module 110 controls the delivery of process gases 114 via the gas supply manifold 112. The chosen gases are then flown into the shower head 150 and distributed in a space volume defined between the showerhead 150 face that faces the wafer 101 and the wafer 101 resting over the pedestal 140.

Further, the gases may be premixed or not. Appropriate valving and mass flow control mechanisms may be employed to ensure that the correct gases are delivered during the deposition and plasma treatment phases of the process. Process gases exit the chamber via an outlet. A vacuum pump (e.g., a one or two stage mechanical dry pump and/or a turbomolecular pump) draws process gases out and maintains a suitably low pressure within the reactor by a close loop controlled flow restriction device, such as a throttle valve or a pendulum valve.

Also shown is a carrier ring 200 that encircles an outer region of the pedestal 140. The carrier ring 200 is configured to sit over a carrier ring support region that is a step down from a wafer support region in the center of the pedestal 140. The carrier ring includes an outer edge side of its disk structure, e.g., outer radius, and a wafer edge side of its disk structure, e.g., inner radius, that is closest to where the wafer 101 sits. FIG. 2 illustrates a substrate processing system that is also configured to perform an atomic layer deposition (ALD) process on a wafer (e.g. an ALD oxide process). Similar componentry as that described with reference to FIG. 1 is shown. However, RF power is supplied to the showerhead 150.

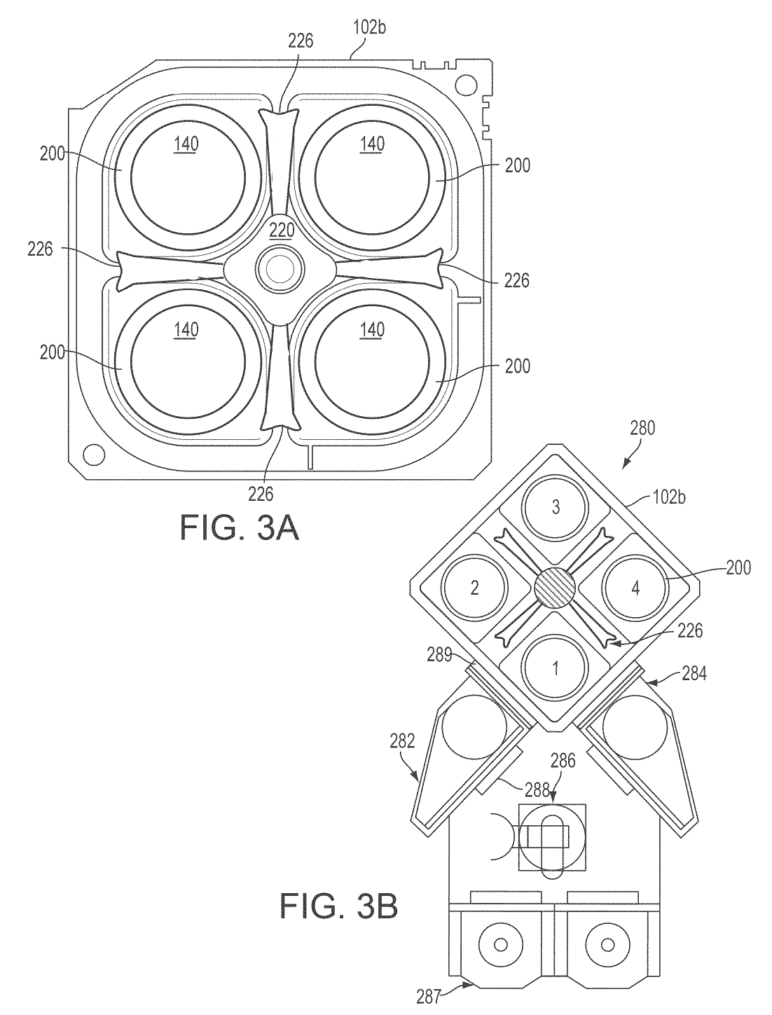

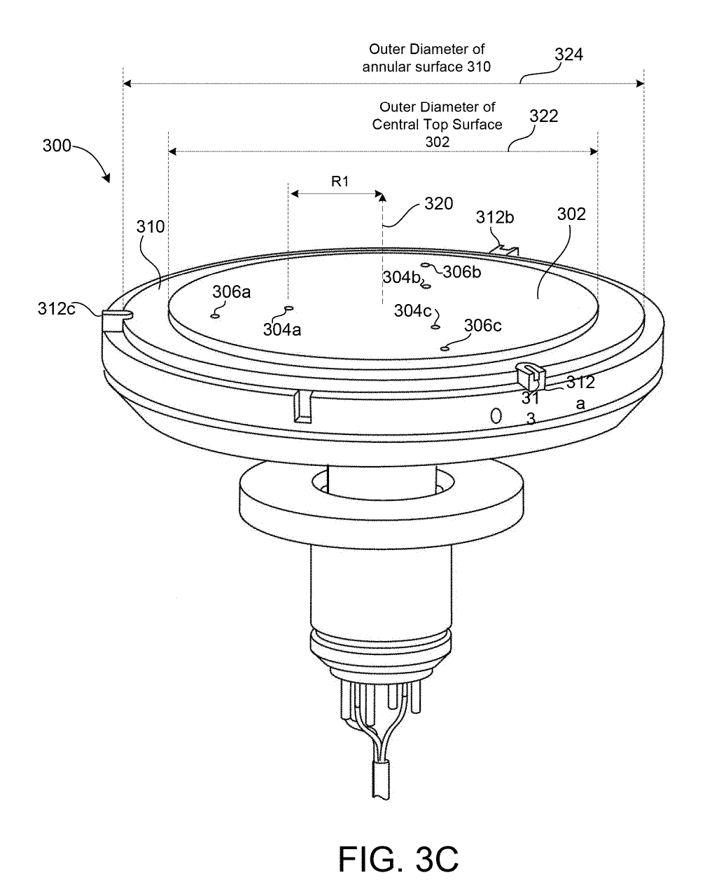

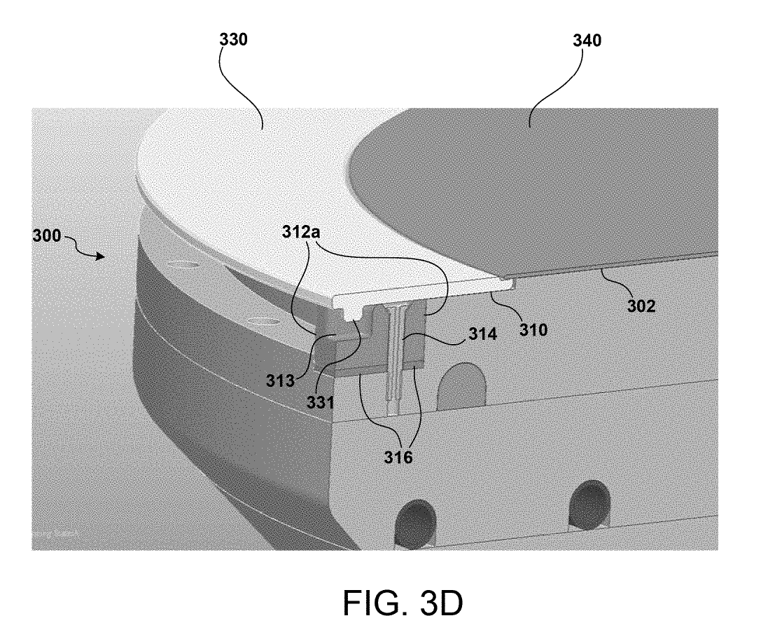

FIG. 3A illustrates a top view of a multi-station processing tool, wherein four processing stations are provided. This top view is of the lower chamber portion 102b (e.g., with the top chamber portion 102a removed for illustration), wherein four stations are accessed by transfer arms 226. The transfer arms 226 are configured to rotate using rotation mechanism 220, which together raise up and lift wafers from the pedestals 140. This configuration is referred to as a ringless wafer transfer system or generally a ringless transfer configuration.

FIG. 3B shows a schematic view of an embodiment of a multi-station processing tool 280 with an inbound load lock 282 and an outbound load lock 284. A robot 286, at atmospheric pressure, is configured to move substrates from a cassette loaded through a pod 287 into inbound load lock 282 via an atmospheric port 288. Inbound load lock 282 is coupled to a vacuum source (not shown) so that, when atmospheric port 288 is closed, inbound load lock 282 may be pumped down. Inbound load lock 282 also includes a chamber transport port 289 interfaced with processing chamber 102b. Thus, when chamber transport 289 is opened, another robot (not shown) may move the substrate from inbound load lock 282 to a pedestal 140 of a first process station for processing.

The depicted processing chamber 102b comprises four process stations, numbered from 1 to 4 (the order is just an example) in the embodiment shown in FIG. 3B. In some embodiments, processing chamber 102b may be configured to maintain a low pressure environment so that substrates may be transferred using transfer arms 226 among the process stations without experiencing a vacuum break and/or air exposure. Each process station depicted in FIG. 3B includes a pedestal.

FIG. 3C illustrates a pedestal 300 that is configured to receive a wafer for a deposition process, such as an atomic layer deposition (ALD) process. The wafer includes a central top surface 302 that is defined by a circular area extending from a central axis 320 of the pedestal to a top surface diameter 322 that defines the edge of the central top surface 302. The central top surface 302 includes a plurality of wafer supports 304a, 304b, and 304c (MCAs) which are defined on the central top surface 302 and configured to support the wafer at a support level above the central top surface. Each wafer support defines a minimum contact area (MCA), and wafer supports 304 are defined from sapphire. MCA's are used to improve precision mating between surfaces when high precision or tolerances are required, and/or minimal physical contact is desirable to reduce defect risk. In one embodiment, the number of wafer supports 304 are selected to provide kinematic mating. In one configuration, at least three wafer supports are needed. In some embodiments, more supports can be used to still achieve kinematic mating. In one embodiment, the wafer support level is defined by the vertical position of the bottom surface of a wafer when seated on the wafer supports.

In one embodiment, the wafer support level for the wafer supports 304 is approximately 2-6 mils (i.e., 0.002-0.006 inch) above the central top surface 302 of the pedestal. In the illustrated embodiment, there are three (3) wafer supports symmetrically distributed about a central circular region of the central top surface 302. In one embodiment, the wafer supports 304a-304c are arranged at about a diameter of about 5 inches around the center, or about 2.5 inches in radius around the center of the central top surface 302 of the pedestal 300.

In other implementations there may be any number of wafer supports on the central top surface 302, which may be distributed about the central top surface 302 in other suitable configurations for supporting the wafer during deposition process operations. Additionally shown are recesses 306a, 306b, and 306c, which are configured to house lift pins. As noted above, the lift pins can be utilized to raise the wafer from the wafer supports to allow for engagement by an end-effector or each of the transfer arms 226.

The pedestal 300 further includes an annular surface 310 extending from the top surface diameter 322 of the pedestal (which is at the outer edge of the central top surface 302) to an outer diameter 324 of the annular surface. The annular surface 310 defines an annular region surrounding the central top surface 302, but at a step down from the central top surface. That is, the vertical position of the annular surface 310 is lower than the vertical position of the central top surface 302. A plurality of carrier ring supports 312a, 312b, and 312c (also referred to as horse shoes) are positioned substantially at/along the edge (outer diameter) of the annular surface 310 and symmetrically distributed about the annular surface. The carrier ring supports can in some embodiments themselves define MCA's for supporting the carrier ring.

In some implementations, the carrier ring supports 312a, 312b, and 312c extend beyond the outer diameter 324 of the annular surface whereas in other implementations they do not. In some implementations, the top surfaces of the carrier ring supports have a height that is slightly higher than that of the annular surface 310, so that when a carrier ring 330 is resting on the carrier ring supports 312, then the carrier ring 330 is supported at a predefined distance above the annular surface. As will be described further below, one embodiment will place a ledge of the carrier ring at a height that is higher than the wafer supports 304. Each carrier ring support 312 may include a recess, such as recess 313 of carrier ring support 312a, in which an extension protruding from the underside of the carrier ring is seated when the carrier ring is supported by the carrier ring supports. The mating of the carrier ring extensions to the recesses in the carrier ring supports provides for secure positioning of the carrier ring and prevents the carrier ring from moving when seated on the carrier ring supports.

In the illustrated embodiment, there are three carrier ring supports positioned symmetrically along the outer edge region of the annular surface. However, in other implementations, there may be three or more carrier ring supports, distributed at any locations along the annular surface 310 of the pedestal 300, to support a carrier ring in a stable resting configuration. It will be appreciated that when the wafer is supported by the wafer supports 304 and the carrier ring 330 is supported by the carrier ring supports 312, then an edge region of the wafer is disposed over an inner portion of the carrier ring 330.

FIG. 3D illustrates a perspective cutaway view of a portion of the pedestal 300 and other components that define part of a pedestal assembly, in accordance with an embodiment of the invention. In one embodiment, a process chamber such as that shown in FIGS. 3A and 3B include four pedestal assemblies. A pedestal assembly includes the pedestal 300, the carrier ring supports 312, and the wafer supports 304, the spacers 316 if optionally used. In one embodiment, the carrier ring 330 is part of the pedestal assembly.

The cutaway view is a longitudinal section intersecting one of the carrier ring supports, e.g. carrier ring support 312a. A carrier ring 330 is shown resting atop the carrier ring support 312a. In this configuration, the carrier ring extension 331 is seated within the recess 313 of the carrier ring support 312a. Also, a wafer 340 is shown resting over the central top surface 302 of the pedestal (supported by wafer supports 304). The carrier ring support 312a is height adjustable, so as to allow the distance above the annular surface 310 at which the carrier ring is supported to be adjusted. In some implementations, the carrier ring support 312a includes a spacer (e.g. a shim) 316 for adjusting the height of the carrier ring supports 312. That is, the spacer 316 is selected to provide for a controlled distance between the carrier ring 330 and the annular surface 310 when the carrier ring is resting on the carrier ring supports. It will be appreciated that there may be zero, one, or more than one spacers 316 selected and positioned beneath the carrier ring support 312a, to provide for the desired distance between the annular surface 310 and the carrier ring 330.

Additionally, the carrier ring support 312a and the spacer(s) 316 are secured to the pedestal by fastening hardware 314. In some implementations, the hardware 314 can be a screw, bolt, nail, pin, or any other type of hardware suitable for securing the carrier ring support and spacer(s) to the pedestal. In other implementations, other techniques/materials for securing the carrier ring support and spacers to the pedestal can be utilized, such as a suitable adhesive.

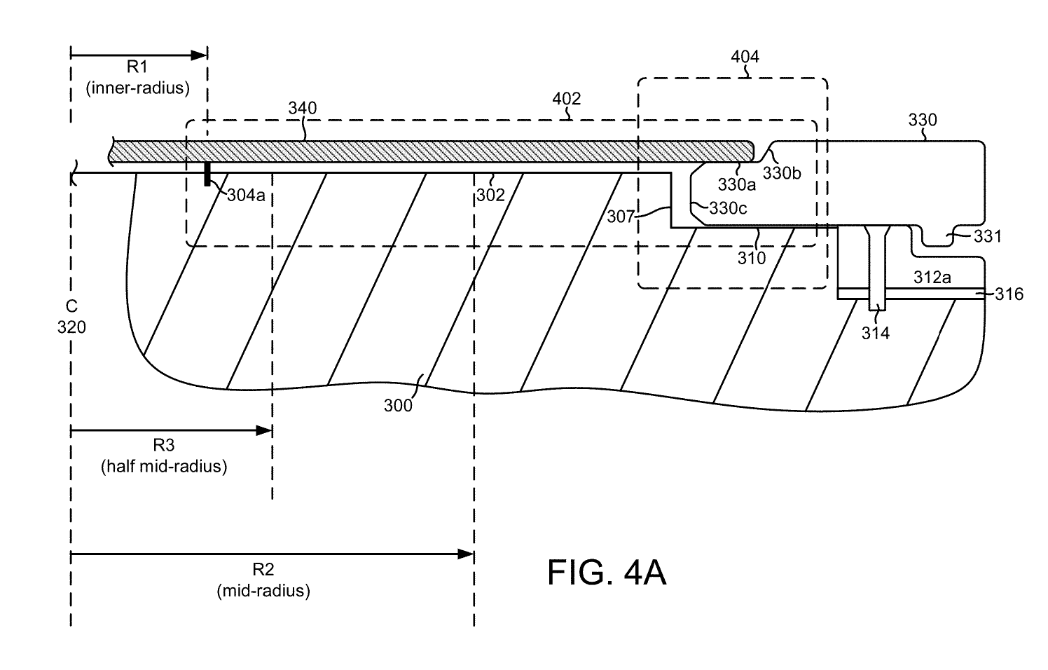

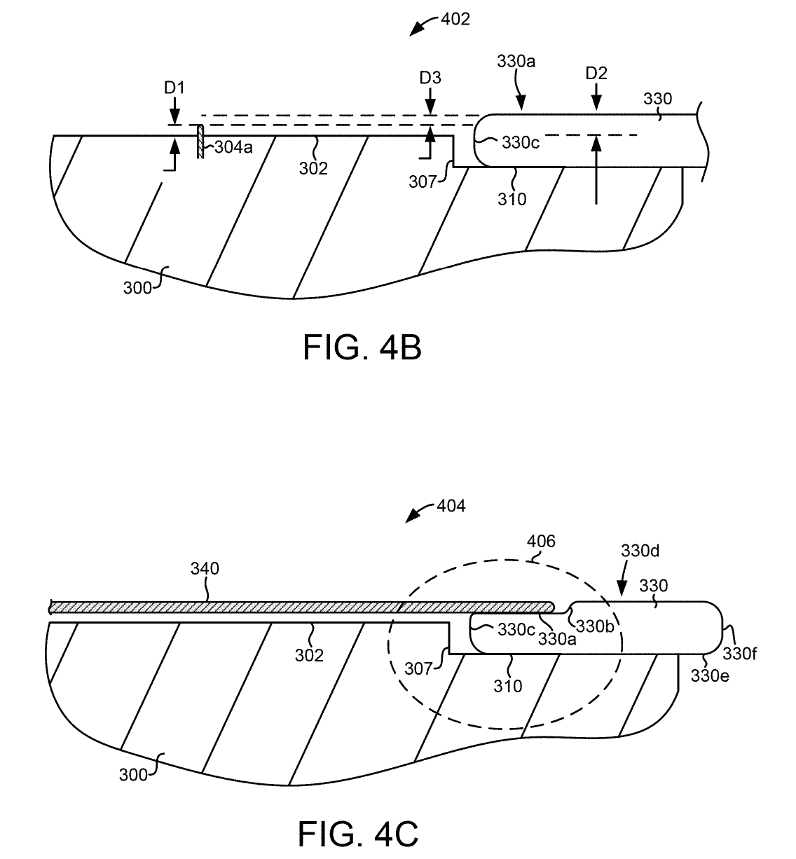

FIG. 4A illustrates a cross-sectional view similar to that of FIG. 3D, with additional detail regarding the wafer support 304a and the contact made by wafer 340 on the ledge surface 330a, in accordance with one embodiment. As shown, the wafer support 304a is disposed in a manner that it extends above the central top surface 302 an amount that provides for maintaining the wafer 340 from directly contacting the central top surface 302. As mentioned above, one embodiment includes providing at least three wafer supports 304a-304c, arranged equally spaced apart at a radius R1, measured from the center 320. Radius R1 is an inner radius. In one embodiment, the radius R1 is about 2.5 inches. In another embodiment, the radius R1 is less than 3 inches and at least 1.5 inches. Further shown is radius R2, which represents the mid-radius relative to the center 320. The mid-radius is approximately halfway between the center 320 and the central top surface outer diameter 307. In one embodiment, if the central top surface has a diameter of about 11.52 inches, the mid-radius R2 is about 5.76 inches In one embodiment, the wafer support 304a will be disposed at a radius R1 that is less than the mid-radius R2.

Further shown in FIG. 4A, is quarter-radius R3, which is about mid-way between the mid-radius R2 and the center 320. The quarter-radius R3, in one embodiment for when the diameter of the central top surface is 11.52 inches, is about 2.88 inches. As noted above, the inner radius R1 is about 2.5 inches. In some embodiments, the inner radius R1 can be about 2.5 inches, plus/minus 0.5 inches. Accordingly, the inner radius R1 can be located either inside of the quarter-radius R3 or past the quarter-radius R3, or at the quarter-radius R3. In either case, the inner radius R1 should generally be less than the mid-radius R2, so that sufficient bend in the wafer will be provided over the wafer supports 304 and the ledge surface 330a.

In one configuration, these dimensions relate to the pedestal 300 that is used for a 300 mm wafer. Of course, these dimensions will change depending upon the size of the wafer being processed. Optimally, the wafer supports 304a are maintained at a radius R1 that will allow a remainder of the wafer 342 to extend out to the ledge surface 330a, where the ledge surface 330a is disposed at a height that is greater than the height of the wafer support 304a. In this manner, the wafer between the wafer support 304a and the ledge surface 330a will slightly bow upwards toward the outer radius. This slight configuration and height differences provides a significant beneficial effect to ensure that the wafer edge remains substantially seeded over the ledge surface 330a, and therefore prevents process gases and precursors from seeping between the carrier ring 330 and depositing films under the wafer. Further, by setting the ledge surface 330a to be higher than the wafer support 304a, was found to also efficiently handle temperature variations during processing, e.g., as parts of the pedestal and the carrier ring tend change in physical size due to thermal expansion and contraction.

FIG. 4A further shows how the carrier ring 330 is seated over the carrier ring support 312a, and a spacer 316. The spacer 316 is used to set the specific height of the carrier ring 330, to achieve the difference in height between the ledge surface 330a and the wafer support 304a. In this example, the difference in height is relative to the central top surface 302 of the pedestal 300. The carrier ring extension 331 is shown to sit within the horseshoe space of the carrier ring support 312a, which is also shown in FIG. 3C. The carrier ring 330 includes an inner diameter 330c, which is placed adjacent to the inner diameter 307 of the pedestal 300. A step 330b is defined on the top surface of the carrier ring 330, where the outer top surface of the carrier ring 330 transitions to the ledge surface 330a, which is disposed in the inner diameter region of the carrier ring 330. In one embodiment, the ledge surface 330a on the carrier ring 330 has a radial length dimension between edge 330c and the step 330b of about 0.007 to about 0.1 inch. Detail regions 402 and 404 will now be discussed with reference to FIGS. 4B and 4C.

FIG. 4B illustrates how the wafer support 304a is disposed in the pedestal 300, and has a portion thereof extending out of the central top surface 302. The amount by which it extends out of the central top surface 302 is shown to be a support elevation distance D1. Support elevation distance D1 in one embodiment is set to be between 2 mils (0.002 inch) and 6 mils (0.006 inch), and in one specific embodiment is set to be about 4 mils (0.004 inch). As mentioned above, the wafer supports 304 are, in one embodiment, defined from a sapphire material. The carrier ring 330 is shown disposed over the annular surface 310, and adjacent to the central top surface outer diameter 307.

The positioning of the carrier ring 330, as mentioned above, can be by way of selecting different weaknesses of the carrier ring 330 or by adjusting spacer 316 to be different thicknesses. In other embodiments, the elevation can also be adjusted by selecting a different height for the carrier ring supports 312. In this example, the carrier ring 330 has a carrier ring elevation dimension D2, relative to the central top surface 302, of between about 1 mil (0.001 inch) and about 3 mil (0.003 inch). In one embodiment, the carrier ring elevation dimension D2 is about 1.5 mils (0.0015 inch).

Generally speaking, carrier ring elevation dimension D2 is relative to the support elevation dimension D1. For example, if D1 is higher, then D2 is likewise higher. Similarly, if D1 is lower, then D2 is likewise lower. By way of another example, the ledge surface 330a is about 0.001 to about 0.0015 inch about the wafer supports 304. In one embodiment, it is preferred that dimension D2 is higher than dimension D1, and the placement of the wafer supports 304 light at a radius that is closer to the center 320 but not greater than the mid-radius R2, e.g., see FIG. 4A. It is again noted that these example dimensions relate to a pedestal 300 and associated structural components that relate to processing a 300 mm wafer. If larger wafers, e.g. 400 mm, or smaller wafers, e.g., 200 mm, are processed, appropriate scaling should be performed.

FIG. 4B further illustrates a carrier-support dimension D3, that represents the difference between the elevations of D1 and D2. As such, D2 is the sum of D1+D3, where the reference for D1 and D2 is the central top surface 302, and the reference for D3 is the elevation of D1.

FIG. 4C illustrates the detail region 404 of FIG. 4A, with more particularity. This illustration is shown to provide detail regarding the desired placement of wafer 340 over the ledge surface 330a of the carrier ring 330. In this example, the carrier ring 330 is shown to include the ledge surface 330a, the carrier ring outer top surface 330d, the carrier ring lower surface 330e, the inner diameter surface 330c, and the step 330b. The step 330b is provided to transition between the ledge surface 330a and the carrier ring outer top surface 330d. The step 330b can have an angle or can be vertical. In one embodiment, the step 330b has a gradual incline transition between the ledge surface 330a and the carrier ring outer top surface 330d. The ledge surface 330a is the top inner region of the carrier ring 330. A top outer region 330g of the carrier ring 330 is also shown, as well as an outer diameter 330f of the carrier ring 330.

In one configuration, the wafer 340 is shown to be in contact with the ledge surface 330a, in a manner that ensures that the outer edge region of the wafer 340 remains seated over the ledge surface 330a during processing. As mentioned above, processing will entail different temperature settings. Example temperature settings may include 50° C., 400° C., and other temperatures lower or higher or in between these temperatures. However, as temperatures rise in the processing chamber, consistent with processing recipes for depositing films, these elevated temperatures will necessarily cause the structural components of the pedestal to change in size due to thermal expansion and thermal contraction.

It has been observed that during elevated temperatures, e.g., reaching 400° C., the carrier ring 330 will expand. As the carrier ring 330 expands, the inner diameter 330 C will also expand outward, leaving a situation where the wafer 340 is no longer properly seated over the ledge surface 330a. When this happens, the wafer 340 may fall in contact the central top surface 302 of the pedestal. It is also possible that the wafer 340 may initially seat over portions of the carrier ring 330, but may remain unstable. In other situations, it is possible the gaps between the wafer edge and the carrier ring 330 will be exposed, which would then allow process gases, precursors, and other chemistries to seep their way under the wafer 340 and thus deposit films thereon. Either of these situations is not beneficial to processing film deposition operations in a chamber that includes the pedestal 300. Thus, in addition to maintaining optimal separation between the wafer support 304a and the ledge surface 330a of the carrier ring, it is preferred that a defined overlap is maintained between the wafer 304 under surface at the edge and the ledge surface 330a.

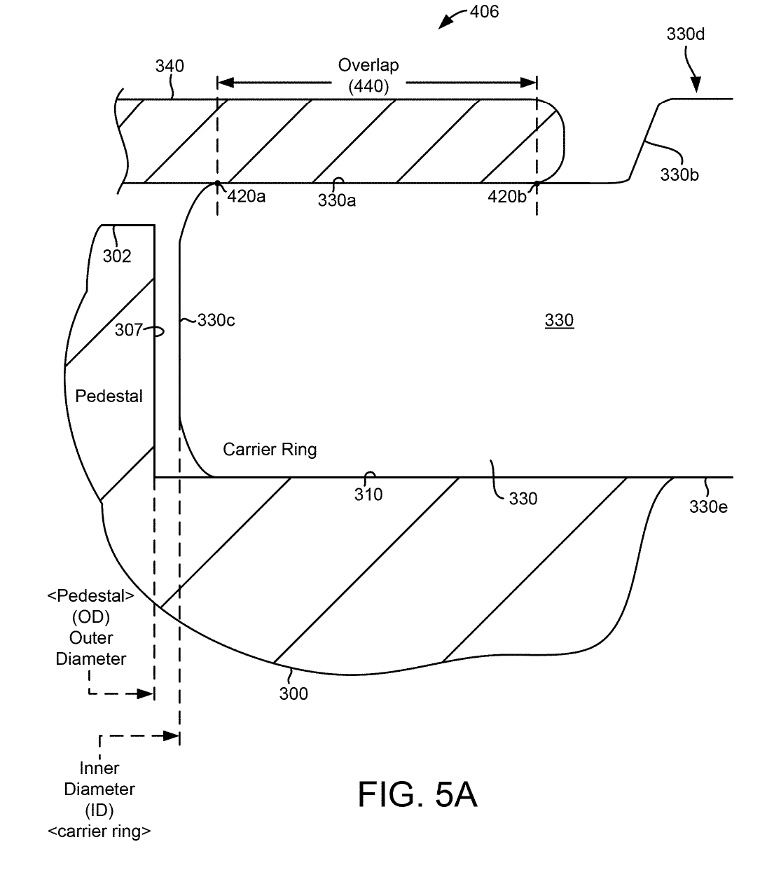

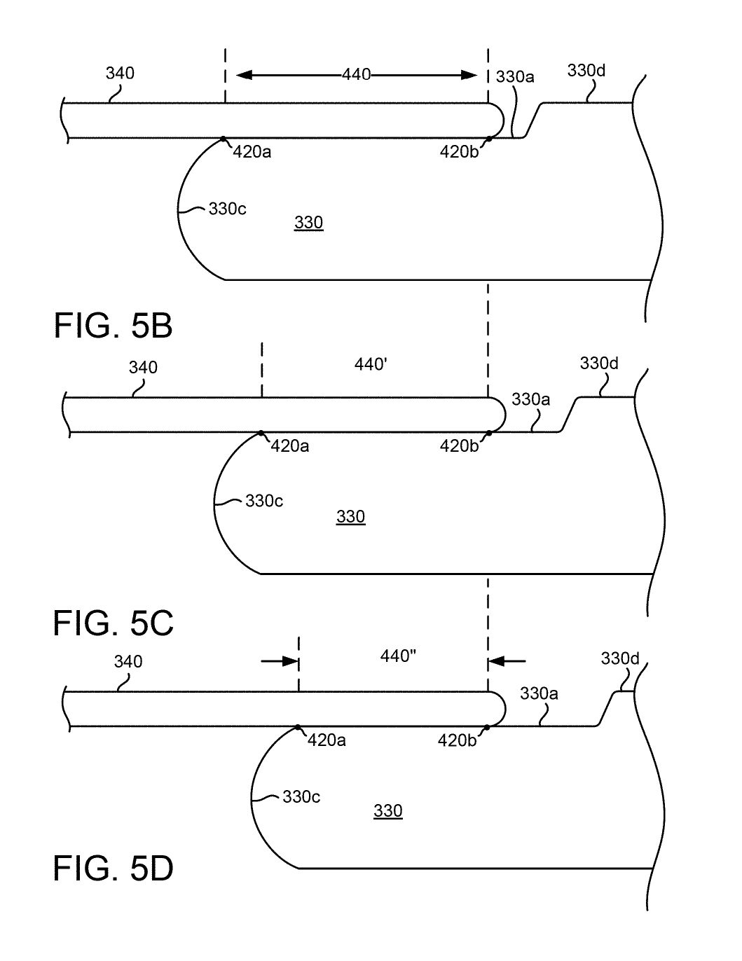

FIG. 5A illustrates detail region 406 of FIG. 4C, which shows an overlap 440 between the under edge surface of the wafer 340 and the ledge surface 330a of the carrier ring 330, in accordance with one embodiment. As shown, an inner overlap point 420a and an outer overlap point 420b, associated with the carrier ring 330. The overlap 440 of the wafer 340 is at a region under the wafer 340 that extends from a point of the underside of the wafer 340 at the non-curved region and extends to the inner overlap point 420a, that defines the edge of the flat portion of the ledge surface 330a. In one embodiment, the carrier ring 330 has an overlap surface 440a.

As shown, the center top surface outer diameter 307 of the pedestal 300 extends an outer diameter OD, while the carrier ring 330 extends to an inner diameter ID that is adjacent to the OD of the pedestal at the center top surface OD 307.

Setting the height of the wafer support 304, the height of the ledge surface 330a, the radius R1 of the wafer supports 304, and a nominal value for the overlap 440 shown in detail 406 ensures that processing of wafer 340 can withstand thermal changes in the components of the pedestal 300 and associated carrier ring 330 during processing. As mentioned above, thermal processing can reach temperatures of 400° C. or higher. When the temperature reaches 400° C., the carrier ring 330 will expand relative to the center top surface outer diameter 307 of the pedestal 300. Therefore, the overlap 440 is further selected to ensure that the bottom surface of the substrate 340 remains seated over the ledge surface 330a all the way around the wafer, and thus prevents seepage of process gases, precursors, and other chemicals in gases that can cause film deposition onto the underside of the wafer.

FIGS. 5B through 5D illustrate an example of the thermal changes that may occur that would impact the overlap 440 shown in FIG. 5A, during thermal processing. For simplification, the overlap is shown between points 420a and 420b, which is the surface under the wafer that is in contact or disposed over the ledge surface 330a. As the temperature increases, it is believed that the carrier ring 330 will expand, which will cause the area in the overlap to decrease. For purposes of illustration, FIG. 5C may depict the situation when processing is occurring at 50° C., and FIG. 5D may depict the situation when processing is occurring at 400° C. As the temperature increases, the overlap 440 decreases to overlap 440′ and then overlap 440″.

FIG. 5D illustrates that the overlap 440″ has decreased substantially, but calibration of the sizing of the carrier ring and positioning relative to the central top surface 302 of the pedestal 300, will ensure that a minimum amount of overlap 440″ will remain, such that a sufficient seal is provided to guard against process gases from entering the gap and finding their way for deposition on the backside of the wafer. The ledge surface 330a that is covered by the wafer 340 represents an overlap surface region of the carrier ring 330. The overlap surface region of the carrier ring 330 will therefore thermally increase and decrease during processing cycles. In accordance with the embodiments disclosed herein, the calibration sizing of these dimensions are designed to provide a functioning support surface for the substrate during the various temperature cycling processes expected for operation in the chamber.

In the below tables, the inner diameter ID is measured to the inner overlap point 420a and the outer diameter OD is measured to the inner overlap point 420b, with reference to FIGS. 5A-5D.

Table A below illustrates the configuration of the sizing of the overlap 440, for a processing system. For a temperature of 50° C., a nominal overlap of about 0.054 inch is observed from testing. During processing, to account for tolerances, the overlap 440 may decrease to about 0.0075 inch. It has been determined that this minimum overlap 440 that results during elevated temperatures of 50° C. is sufficient to maintain the wafer 340 seated over the ledge surface 330a, while still preventing process gases from flowing under the wafer.

TABLE A

| Dimension | Process Temp 50 C. (inch) |
|---|---|
| OD 420b | 11.773 |
| ID 420a | 11.664 |
| Nominal Overlap 440 | 0.0545 |
| Tolerance Limit | 0.023 |
| CR + Wafer Placement | 0.024 |
| Min Overlap 440 | 0.0075 |

Table B also illustrates another embodiment and associated dimensions for a configuration for 50° C. processing. In this example, the nominal overlap 440 was determined to be 0.064. The minimum overlap 440 at process temperatures of 50° C. result in about 0.025 inch overlap. This provides a slightly larger overlap during processing temperatures of 50° C., as compared to the example of table A.

TABLE B

| Dimensions | Process Temp 50 C. (inch) |
|---|---|
| OD 420b | 11.773 |
| ID 420a | 11.645 |
| Nominal Overlap 440 | 0.064 |
| Tolerance Limit | 0.021 |
| CR + Wafer Placement | 0.018 |
| Min. Overlap 440 | 0.025 |

The configurations of tables C and D relate to processing temperatures of about 400° C., as an example. Table C shows a configuration where the nominal overlap is 0.016 inch. This produces a negative number for the minimum overlap 440, which may fail to adequately block sufficient amounts of process gases from seeping under the wafer via gaps produce between the wafer and the carrier ring 330.

TABLE C

| Dimensions | Process Temp 400 C. (inch) |
|---|---|
| OD 420b | 11.784 |
| ID 420a | 11.752 |
| Nominal Overlap 440 cold | 0.016 |
| Tolerance Limit | 0.023 |
| CR + Wafer Placement | 0.024 |
| Min. Overlap 440 | −0.031 |

Table D below illustrates the configuration of the sizing of the overlap 440 to increase the nominal overlap to about 0.064 inch. During processing, the temperature will elevate to about 400° C., which causes the overlap 440 to decrease to about 0.017 inch. It has been determined that this minimum overlap 440 that results during elevated temperatures of 400° C. is sufficient to maintain the wafer 340 seated over the ledge surface 330a, while still preventing process gases from flowing under the wafer. Furthermore, in the embodiment of table D, the center top surface outer diameter 307 was reduced to about 11.52 inches, while also decreasing the inner diameter of the carrier ring 330 to about 11.71 inches at the surface 330c to about 11.63″ inches.

TABLE D

| Dimensions | Process Temp 400 C. (inch) |
|---|---|
| OD 420b | 11.784 |
| ID 420a | 11.672 |
| Nominal Overlap 440 | 0.056 |
| Tolerance Limit | 0.021 |
| CR + Wafer Placement | 0.018 |
| Min. Overlap 440 | 0.017 |

In the example illustrations of the pedestal 300 and associated components, example materials will now be discussed. The pedestal 300 is preferably made from aluminum. The carrier ring 330 is preferably made from a ceramic, such as aluminum oxide. The carrier ring supports 312 are preferably made from a ceramic, such as aluminum oxide. The wafer supports 304 are made from sapphire and sized to fit within recess is made into the central top surface 302 of the pedestal 300, so as to define support elevation dimension D1. It is envisioned that for each station in which a pedestal is placed in a processing chamber, the dimensions associated with placing the carrier ring 330 relative to the wafer supports 304 in the pedestal will be individually calibrated and set for processing.

As such, by calibrating each station to the desired relative dimensions, it is possible to maintain consistency in deposition performance of wafers 340, while also preventing backside deposition on the processed wafers. This provides for repeatability of process operations, which also increases processing yields. By individually calibrating each station, inherent variability in component manufacturing parts is reduced, since each station will be appropriately dimensioned and adjusted to meet the desired elevations D1, D2, and D3, as described with reference to FIG. 4B. Additionally, the desired overlap 440 can be tailored for each processing station, given the desired process temperature ranges to be performed for specific recipes in the processing chamber/reactor.

As mentioned above, previous hardware setups were not optimized for wafer contact with the carrier ring 330 to prevent gaps from occurring between the wafer and the carrier ring. Improving the wafer contact and lifting the carrier ring to be slightly above the MCA pins, the performance is improved at reducing deposition and repeatability of its performance. The combination of the elements with the carrier ring being set above the MCA pins, therefore provides substantial improvements in tool performance. Another feature providing these benefits is a reduction in OD 307 of the mesa 302 of the pedestal 300 to enable wider carrier ring 330 (e.g., having a smaller ID 330c).

A wider carrier ring 330 will thus increase backside overlap of wafer and wafer notch area. In one embodiment, a carrier ring 330 has an annular total width of about 1.67 inches, nominally (i.e., in a radial length). The overlap is about 0.06 inch, nominally; and the ledge width is about 0.12 inch, nominally. These are example nominal dimensions, and it should be understood that they may vary, depending on the implementation.

Reduced wafer movement within a pocket via slow pressure ramp and pump-to-base prior to wafer exit from processing, is also utilized in one embodiment. The heights of the components are also calibrated, as mentioned above. Because the carrier ring 330 will remain fixed to the station (pedestal 300), and wafers are delivered and removed by the transfer arms 226, the system is regarded as a ringless wafer transfer indexing system.

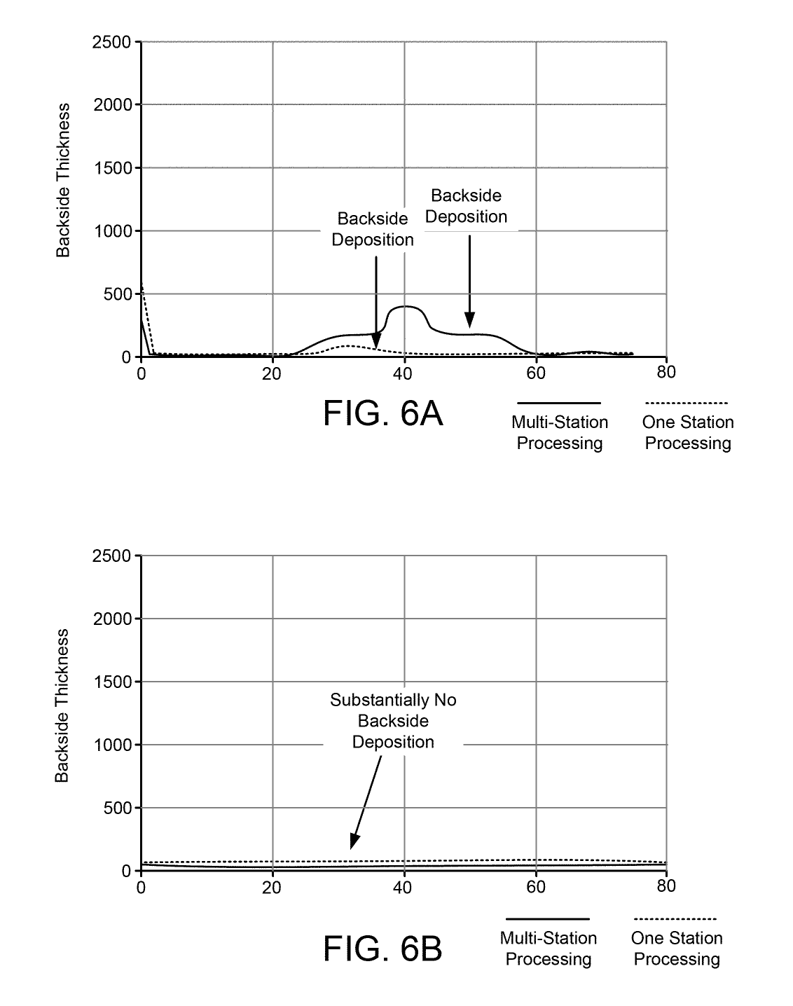

FIGS. 6A and 6B illustrate examples of reduced or substantially eliminated backside deposition to a wafer. As shown, when a gap is present between the wafer edge and the carrier ring 330, or the carrier ring 330 is either at the same level as the wafer supports 304 or lower, it was experimentally shown that backside deposition would occur. Tests were performed on wafer processing operations where the wafer remains in a single station, and also wafer processing operations where the wafer was moved from station to station. In both cases, as shown in FIG. 6A, backside deposition was detected. In FIG. 6B, implementing the configurations described in this application, backside deposition was substantially eliminated. The dimensions are shown without specific call out to units, as these values can change depending on tests performed. The data, however, when normalized, shows that backside deposition was substantially eliminated when the configurations are made in accordance with the various teachings enumerated in this disclosure.

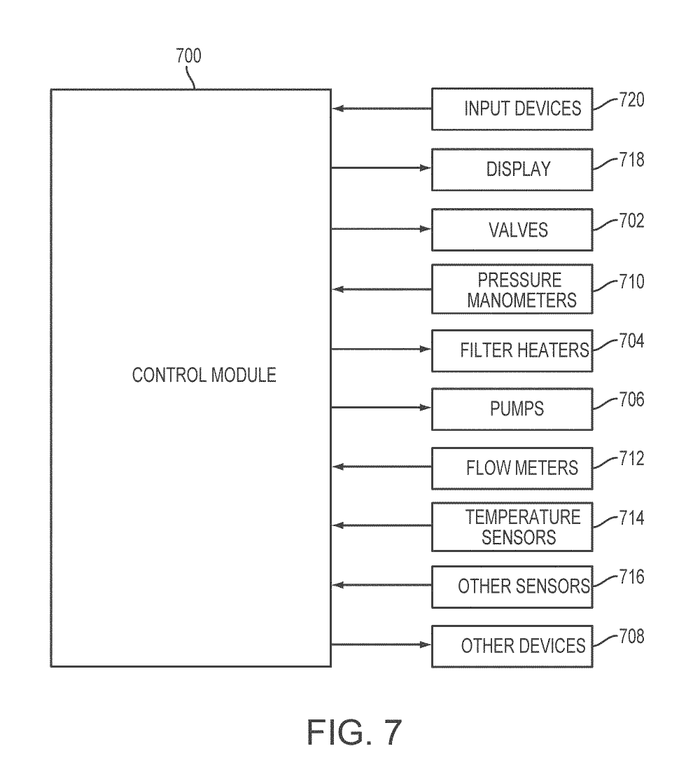

FIG. 7 shows a control module 700 for controlling the systems described above. In one embodiment, the control module 110 of FIG. 1 may include some of the example components. For instance, the control module 700 may include a processor, memory and one or more interfaces. The control module 700 may be employed to control devices in the system based in part on sensed values. For example only, the control module 700 may control one or more of valves 702, filter heaters 704, pumps 706, and other devices 708 based on the sensed values and other control parameters. The control module 700 receives the sensed values from, for example only, pressure manometers 710, flow meters 712, temperature sensors 714, and/or other sensors 716. The control module 700 may also be employed to control process conditions during precursor delivery and deposition of the film. The control module 700 will typically include one or more memory devices and one or more processors.

The control module 700 may control activities of the precursor delivery system and deposition apparatus. The control module 700 executes computer programs including sets of instructions for controlling process timing, delivery system temperature, pressure differentials across the filters, valve positions, mixture of gases, chamber pressure, chamber temperature, wafer temperature, RF power levels, wafer chuck or pedestal position, and other parameters of a particular process. The control module 700 may also monitor the pressure differential and automatically switch vapor precursor delivery from one or more paths to one or more other paths. Other computer programs stored on memory devices associated with the control module 700 may be employed in some embodiments.

Typically there will be a user interface associated with the control module 700. The user interface may include a display 718 (e.g. a display screen and/or graphical software displays of the apparatus and/or process conditions), and user input devices 720 such as pointing devices, keyboards, touch screens, microphones, etc.

Computer programs for controlling delivery of precursor, deposition and other processes in a process sequence can be written in any conventional computer readable programming language: for example, assembly language, C, C++, Pascal, Fortran or others. Compiled object code or script is executed by the processor to perform the tasks identified in the program.

The control module parameters relate to process conditions such as, for example, filter pressure differentials, process gas composition and flow rates, temperature, pressure, plasma conditions such as RF power levels and the low frequency RF frequency, cooling gas pressure, and chamber wall temperature.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A filter monitoring program includes code comparing the measured differential(s) to predetermined value(s) and/or code for switching paths. A pressure control program may include code for controlling the pressure in the chamber by regulating, e.g., a throttle valve in the exhaust system of the chamber. A heater control program may include code for controlling the current to heating units for heating components in the precursor delivery system, the substrate and/or other portions of the system. Alternatively, the heater control program may control delivery of a heat transfer gas such as helium to the wafer chuck.

Examples of sensors that may be monitored during deposition include, but are not limited to, mass flow control modules, pressure sensors such as the pressure manometers 710, and thermocouples located in delivery system, the pedestal or chuck (e.g. the temperature sensors 714). Appropriately programmed feedback and control algorithms may be used with data from these sensors to maintain desired process conditions. The foregoing describes implementation of embodiments of the invention in a single or multi-chamber semiconductor processing tool.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

Although the foregoing embodiments have been described in some detail for purposes of clarity of understanding, it will be apparent that certain changes and modifications can be practiced within the scope of the appended claims.

Accordingly, the present embodiments are to be considered as illustrative and not restrictive, and the embodiments are not to be limited to the details given herein, but may be modified within their scope and equivalents of the claims.

What is claimed is:

1. A pedestal assembly for a plasma processing system, comprising,
a pedestal, including,
a central top surface, the central top surface extends from a center of the central top surface to an outer diameter of the central top surface;
an annular surface that surrounds the central top surface, the annular top surface is disposed at step down from the central top surface;
a plurality of wafer supports project out of the central top surface at a support elevation distance above the central top surface, the plurality of wafer supports being evenly arranged around an inner radius of the center top surface, the inner radius is located between the center of the central top surface and less than a mid-radius, the mid-radius defined approximately half way between the center of the pedestal and the outer diameter of the central top surface;
a carrier ring configured for positioning over the annular surface of the pedestal, the carrier ring has a carrier ring inner diameter, a carrier ring outer diameter, and a ledge surface that is annularly disposed around a top inner region of the carrier ring, the ledge surface is recessed below a top outer region of the carrier ring; and
a plurality of carrier ring supports disposed outside of the annular surface of the pedestal, the carrier ring supports define a carrier ring elevation dimension of the carrier ring, above the central top surface of the pedestal, when the carrier ring rests upon the plurality of carrier ring supports, the carrier ring elevation dimension is configured to be higher than the central top surface of the pedestal than the support elevation distance.

2. The pedestal assembly of claim 1, wherein the plurality of wafer supports provide kinematic mating to a wafer when placed over the plurality of wafer supports.

3. The pedestal assembly of claim 1, wherein the ledge surface of the carrier ring has a step that transitions to the top outer region of the carrier ring, the ledge surface being elevated above the plurality of wafer supports by a carrier ring-support dimension.

4. The pedestal assembly of claim 1, wherein the inner radius is about 2.5 inches and the outer diameter of the central top surface is about 11.5 inches.

5. The pedestal assembly of claim 1, wherein an overlap surface region is defined over the ledge surface, the overlap surface region defines a contact surface for a wafer under surface when disposed over the central top surface of the pedestal.

6. The pedestal assembly of claim 1, wherein a plurality of spacers is disposed under the carrier ring supports to define a calibrated positioning of the carrier ring elevation dimension.

7. The pedestal assembly of claim 1, wherein the inner radius of the plurality of wafer supports located between the center and a quarter-radius, the quarter-radius located between the mid-radius and the center.

8. The pedestal assembly of claim 1, wherein the support elevation distance is between about 2 mils and about 6 mils, and the carrier ring elevation dimension is between about 1 mil and about 3 mils.

9. The pedestal assembly of claim 1, wherein the support elevation distance is about 4 mils and the carrier ring elevation dimension is about 1.5 mils, and the inner radius is about 2.5 inches about the center of the central top surface of the pedestal.

10. The pedestal assembly of claim 9, wherein the outer diameter of the central top surface is about 11.52 inches.

11. The pedestal assembly of claim 1, wherein the support elevation distance is between about 2 mils and about 6 mils, and the carrier ring elevation dimension is between about 1 mil and about 3 mils, and the inner radius of the plurality of wafer supports located between the center and a quarter-radius, the quarter-radius located between the mid-radius and the center, and the plurality of wafer supports provide kinematic mating to a wafer when placed over the plurality of wafer supports.

12. The pedestal assembly of claim 1, wherein the support elevation distance is about 4 mils and the carrier ring elevation dimension is about 1.5 mils, and the inner radius is about 2.5 inches about the center of the central top surface of the pedestal, and the inner radius of the plurality of wafer supports located between the center and a quarter-radius, the quarter-radius located between the mid-radius and the center, and the plurality of wafer supports provide kinematic mating to a wafer when placed over the plurality of wafer supports, the wafer when placed over the plurality of wafer supports and the ledge surface of the carrier ring is configured to angle slightly up from the center to the edge, due to the carrier ring elevation distance being greater than the support elevation distance.

13. The pedestal assembly of claim 1, wherein the plasma processing system is configured as a ringless transfer system, a ringless transfer system is configured to maintain the carrier ring disposed over the annular surface of the pedestal and a wafer is configured to be moved on and off the plurality of wafer supports and the ledge surface of the carrier ring, the pedestal includes lift pins for raising and lowering the wafer when present and the process system includes transfer arms for moving wafers on and off of each one of a plurality of pedestal assemblies of the plasma processing system.

14. A pedestal assembly for a plasma processing system, the plasma processing system having a ringless transfer configuration for moving wafers onto and off of one or more pedestal assemblies disposed in the plasma processing system, comprising,
a pedestal, including,
a central top surface, the central top surface extends from a center of the central top surface to an outer diameter of the central top surface;
an annular surface that surrounds the central top surface, the annular top surface is disposed at step down from the central top surface;
a plurality of wafer supports project out of the central top surface at a support elevation distance above the central top surface, the plurality of wafer supports being evenly arranged around an inner radius of the center top surface, the inner radius is located between the center of the central top surface and less than a mid-radius, the mid-radius defined approximately half way between the center of the pedestal and the outer diameter of the central top surface;
a carrier ring configured for positioning over the annular surface of the pedestal, the carrier ring has a carrier ring inner diameter, a carrier ring outer diameter, and a ledge surface that is annularly disposed around a top inner region of the carrier ring, the ledge surface is recessed below a top outer region of the carrier ring;
a plurality of carrier ring supports disposed outside of the annular surface of the pedestal, the carrier ring supports define a carrier ring elevation dimension of the carrier ring, above the central top surface of the pedestal, when the carrier ring rests upon the plurality of carrier ring supports, the carrier ring elevation dimension is configured to be higher than the central top surface of the pedestal than the support elevation distance; and
a plurality of lift pins for raising and lowering a wafer onto the plurality of wafer supports and the ledge surface of the carrier ring.

15. The pedestal assembly of claim 14, wherein the plurality of wafer supports provide kinematic mating to the wafer when placed over the plurality of wafer supports, and where the ledge surface of the carrier ring has a step that transitions to the top outer region of the carrier ring, the ledge surface being elevated above the plurality of wafer supports by a carrier ring-support dimension.

16. The pedestal assembly of claim 14, wherein the inner radius is about 2.5 inches and the outer diameter of the central top surface is about 11.5 inches, and an overlap surface region is defined over the ledge surface, the overlap surface region defines a contact surface for a wafer under surface when disposed over the central top surface of the pedestal.

17. The pedestal assembly of claim 16, wherein a plurality of spacers are disposed under the carrier ring supports to define a calibrated positioning of the carrier ring elevation dimension.

18. The pedestal assembly of claim 14, wherein the support elevation distance is between about 2 mils and about 6 mils, and the carrier ring elevation dimension is between about 1 mil and about 3 mils.

19. The pedestal assembly of claim 14, wherein the support elevation distance is between about 2 mils and about 6 mils, and the carrier ring elevation dimension is between about 1 mil and about 3 mils, and the inner radius of the plurality of wafer supports located between the center and a quarter-radius, the quarter-radius located between the mid-radius and the center, and the plurality of wafer supports provide kinematic mating to a wafer when placed over the plurality of wafer supports.

20. The pedestal assembly of claim 14, wherein the support elevation distance is about 4 mils and the carrier ring elevation dimension is about 1.5 mils, and the inner radius is about 2.5 inches about the center of the central top surface of the pedestal, and the inner radius of the plurality of wafer supports located between the center and a quarter-radius, the quarter-radius located between the mid-radius and the center, and the plurality of wafer supports provide kinematic mating to a wafer when placed over the plurality of wafer supports, the wafer when placed over the plurality of wafer supports and the ledge surface of the carrier ring angles slightly up from the center to the edge, due to the carrier ring elevation distance being greater than the support elevation distance.
